(19) United States
(12) Patent Application Publication
(10) Pub. No.: US 2024/0006919 A1
(43) Pub. Date: Jan. 4, 2024

(54) COMPACT HYBRID METAL CORE AND INDUCTOR PCB RECTIFIER FOR EV WIRELESS CHARGING

(71) Applicant: Toyota Motor Engineering & Manufacturing North America, Inc., Plano, TX (US)

(72) Inventors: Yanghe Liu, Ann Arbor, MI (US); Guanliang Liu, Livonia, MI (US); Mengqi Wang, Troy, MI (US); Feng Zhou, Ann Arbor, MI (US); Hiroshi Ukegawa, South Lyon, MI (US)

(73) Assignees: Toyota Motor Engineering & Manufacturing North America, Inc., Plano, TX (US); The Regents of the University of Michigan, Ann Arbor, MI (US); Toyota Jidosha Kabushiki Kaisha, Aichi Prefecture (JP)

(21) Appl. No.: 17/856,486

(22) Filed: Jul. 1, 2022

(51) Int. Cl. H02J 50/12; H02M 7/00; H05K 1/18; H05K 1/11; H05K 3/30; B60L 53/12

(52) U.S. Cl. CPC H02J 50/12; H02M 7/003; H05K 1/181; H05K 1/111; H05K 3/30; B60L 53/12; H02J 2207/20; H05K 2201/10015

(57) ABSTRACT

A rectifier apparatus for a wireless inductive charging system includes a first PCB having a metal layer, a dielectric layer provided on a surface of the metal layer, and a circuit layer provided on an opposite surface of the dielectric layer relative to the metal layer, the circuit layer including copper traces and circuit components, the circuit components including a capacitor array. The apparatus includes a second PCB having a non-metallic substrate and a plurality of inductors formed in the non-metallic substrate, each inductor comprised of a magnetic core and metallic windings, where the plurality of inductors are electrically coupled forming an inductor array. The circuit layer of the first PCB and the inductor array of the second PCB are electrically coupled to form a rectifier circuit to provide DC power. The circuit layer and the inductor array can be electrically coupled via aligned contact pads on each PCB.

### TECHNICAL FIELD

Embodiments generally relate to electric vehicle charging systems. More particularly, embodiments relate to a streamlined rectifier apparatus for wireless electric vehicle charging.

### BACKGROUND

Wireless inductive charging systems for electric vehicles (EVs) include a receiver and rectifier to transfer power from a magnetic or electromagnetic field, applied in the vicinity of the receiver, to electric power for the vehicle. The receiver is typically placed or mounted on the bottom of the electric vehicle (EV) such that a transmitter can be placed in proximity to the receiver to expose the receiver to a changing magnetic field. Conventional rectifier circuits are bulky with thick passive components (such as capacitors and inductors). Moreover, heat pipes are needed to dissipate heat from switches in the rectifier. As a result, the combination of these components results in a large rectifier circuit package that takes up valuable space and/or precludes placement in some vehicle locations.

### BRIEF SUMMARY

In some embodiments, a rectifier apparatus for a wireless inductive charging system includes a first printed circuit board (PCB) including a plurality of layers, the plurality of layers including a metal layer, a dielectric layer provided on a surface of the metal layer, and a circuit layer provided on an opposite surface of the dielectric layer relative to the metal layer, the circuit layer including copper traces and circuit components, the circuit components including a capacitor array, and a second PCB including a non-metallic substrate, and a plurality of inductors formed in the non-metallic substrate, each inductor comprised of a magnetic core and a plurality of metallic windings, where the plurality of inductors are electrically coupled to form an inductor array, where the circuit layer of the first PCB and the inductor array of the second PCB are electrically coupled to form a rectifier circuit to provide direct current (DC) power.

In some embodiments, a method of constructing a rectifier apparatus for a wireless inductive charging system includes assembling a first printed circuit board (PCB) including a plurality of layers, the plurality of layers including a metal layer, a dielectric layer provided on a surface of the metal layer, and a circuit layer provided on an opposite surface of the dielectric layer relative to the metal layer, the circuit layer including copper traces and circuit components, the circuit components including a capacitor array, assembling a second PCB including a non-metallic substrate, and a plurality of inductors formed in the non-metallic substrate, each inductor comprised of a magnetic core and a plurality of metallic windings, where the plurality of inductors are electrically coupled to form an inductor array, and electrically coupling the circuit layer of the first PCB and the inductor array of the second PCB to form a rectifier circuit to provide direct current (DC) power.

In some embodiments, an electric vehicle wireless charging apparatus including a rectifier includes a first printed circuit board (PCB) including a plurality of layers, the plurality of layers including a metal layer, a dielectric layer provided on a surface of the metal layer, and a circuit layer provided on an opposite surface of the dielectric layer relative to the metal layer, the circuit layer including copper traces and circuit components, the circuit components including a capacitor array, and a second PCB including a non-metallic substrate, and a plurality of inductors formed in the non-metallic substrate, each inductor comprised of a magnetic core and a plurality of metallic windings, where the plurality of inductors are electrically coupled to form an inductor array, where the circuit layer of the first PCB and the inductor array of the second PCB are electrically coupled to form a rectifier circuit to provide direct current (DC) power, and a receiver electrically coupled to the rectifier, the receiver including an inductive coil to generate electric power when exposed to a changing magnetic field.

### BRIEF DESCRIPTION OF THE SEVERAL VIEWS OF THE DRAWINGS

The various advantages of the embodiments of the present disclosure will become apparent to one skilled in the art by reading the following specification and appended claims, and by referencing the following drawings, in which:

FIGS. 1A-1C provide diagrams illustrating an example of a wireless inductive charging system for use in an electric vehicle according to one or more embodiments;

FIGS. 2A-2C provide diagrams illustrating examples of circuitry for use in a rectifier apparatus according to one or more embodiments;

FIGS. 3A-3B provide diagrams illustrating examples of a metal core PCB for use in a rectifier apparatus according to one or more embodiments;

FIG. 4A provides a diagram illustrating an example of an inductor PCB for use in a rectifier apparatus according to one or more embodiments;

FIGS. 4B-4D provide diagrams illustrating an example of an inductor for an inductor board for use in a rectifier apparatus according to one or more embodiments;

FIGS. 5A-5C provide diagrams illustrating examples of a dual rectifier board apparatus for use in a wireless inductive charging system according to one or more embodiments; and

FIGS. 6A-6B provide flowcharts illustrating an example method of constructing a rectifier apparatus for a wireless inductive charging system according to one or more embodiments.

### DETAILED DESCRIPTION

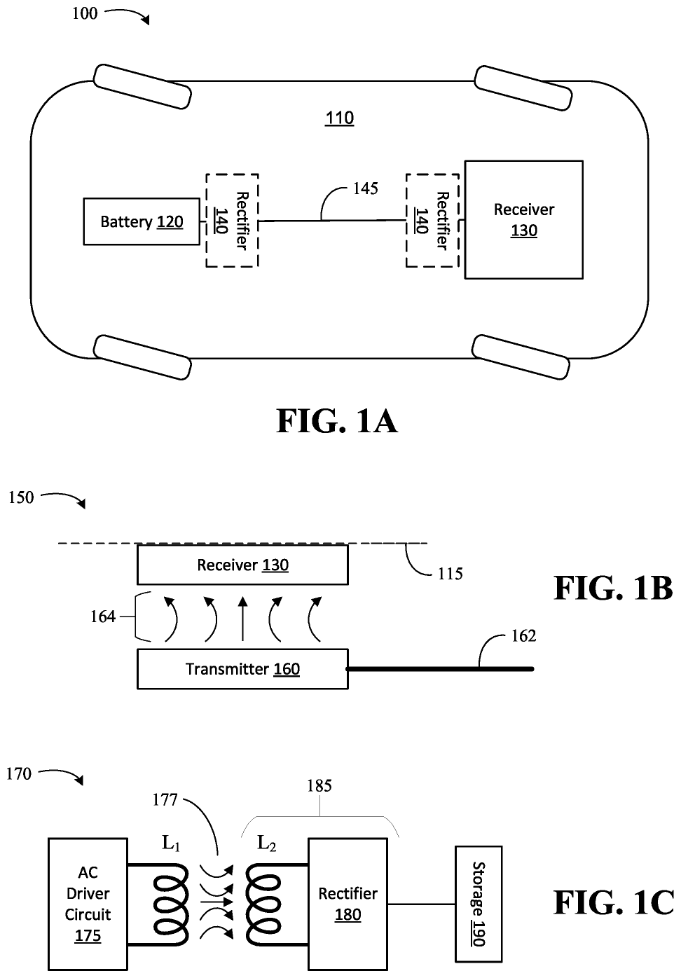

FIG. 1A provides a diagram illustrating an example of a wireless inductive charging system 100 for use in an electric vehicle (such as, e.g., an electric vehicle 110) according to one or more embodiments, with reference to components and features described herein including but not limited to the figures and associated description. The charging system 100 includes a battery 120 to store and supply electric power to the electric vehicle (EV) 110. The charging system 100 further includes a receiver 130 that, in combination with a rectifier 140, converts a magnetic field (which can be an electromagnetic field) (not shown in FIG. 1A) applied in the vicinity of the receiver 130 into electric power to charge the battery 120. The receiver 130 is located in a place on the EV 110 that is accessible to provide the electromagnetic field via an external transmitter (not shown in FIG. 1A). For example, the receiver 130 can be located on the bottom of the EV 110.

The receiver 130 is electrically coupled to the rectifier 140 which, in turn, is electrically coupled to the battery 120. A wire or cable 145 can be used to connect one or more of the receiver 130, the rectifier 140 and the battery 120. The receiver 130 is comprised of one or more inductive coils, and operates on the principal of inductive coupling (which can be, e.g., resonant inductive coupling) in which electric power is transferred from a source (e.g., a transmitter, not shown in FIG. 1A) to the receiver 130 via a magnetic field generated by the source. The rectifier 140 can be located at a variety of locations between the receiver 130 and the battery 120. For example, in embodiments the rectifier 140 can be located proximate to the receiver 130. As another example, in embodiments the rectifier 140 can be integrated with the receiver 130. As another example, in embodiments the rectifier 140 can be located proximate to the battery 120. In any of such arrangements, when the rectifier 140 is located on the bottom of the EV 110, vertical space is limited. Accordingly, as described more fully herein, the rectifier 140 is designed to reduce the amount of vertical space needed to place the rectifier 140 assembly on the bottom of the EV 110.

FIG. 1B provides a diagram illustrating an example of a wireless inductive charging system 150 for use in an electric vehicle (such as, e.g., the electric vehicle 110) according to one or more embodiments, with reference to components and features described herein including but not limited to the figures and associated description. The wireless inductive charging system 150 is illustrated in FIG. 1B from the perspective of a side or rear view of the EV 110. The receiver 130 (FIG. 1A, already discussed) is mounted or attached to an underside 115 of the EV 110. The receiver 130 is designed such that there is room for placement of a transmitter 160 underneath and in proximity to the receiver 130 such that, when electric power is provided to the transmitter 160 such as, e.g., via a cable 162, a changing magnetic field 164 (which can be an electromagnetic field) is generated which passes (e.g., permeates or radiates) into the receiver 130. The receiver 130 in combination with the rectifier 140 transfers power from the magnetic field 164 into electric power via inductive coupling to charge the battery 120. In this way, the receiver 130 generates (e.g., provides) electric power when exposed to a changing magnetic field. For example, the receiver 130 provides AC input power to the rectifier 140 which, in turn, generates DC output power for charging the battery 120.

In some embodiments, the transmitter 160 can be a portable or moveable device that is placed under the receiver 130 during charging and then removed once the charging process is finished. In some embodiments, the transmitter 160 can be a stationary device, while the EV 110 is moved into an appropriate position such that the receiver 130 is located above the transmitter 160 during the charging process.

Placement of the receiver 130 and the rectifier 140 such as, e.g., on the bottom of the EV 110 means that the rectifier 140 should be designed to minimize the vertical size or height of the rectifier apparatus. As mentioned above, conventional rectifier circuits are bulky with thick passive components (such as capacitors and inductors), and heat pipes are needed to dissipate heat from switches in the rectifier. According to embodiments, a rectifier apparatus as described herein provides for reducing and/or minimizing the vertical space required in one or more ways, including: providing a cooling mechanism using a metal core PCB to eliminate the need for heat pipes; providing for the use of thin surface-mount capacitors (e.g., in one or more capacitor arrays) instead of conventional bulky “can” capacitors; and providing for the use of Inductor s instead of conventional bulky board-mounted inductors.

FIG. 1C provides a diagram illustrating an example of a wireless charging circuit 170 for use in an electric vehicle wireless inductive charging system such as, e.g., the wireless inductive charging system 150 according to one or more embodiments, with reference to components and features described herein including but not limited to the figures and associated description. The wireless charging circuit 170 can include an AC driver circuit 175, a first coil or inductor L₁, a second coil or inductor L₂, a rectifier 180 and an electric storage device (e.g., a battery) 190. The AC driver circuit 175 is configured to provide AC power to the first coil L₁ sufficient to generate a changing magnetic field 177 which, in turn, passes (e.g., permeates or radiates) into the second coil L₂ when the second coil L₂ is in proximity to the first coil L₁. The AC driver circuit is further configured such that, in conjunction with the first coil L₁, the provided AC power is of a selected frequency.

In embodiments, the selected frequency of the AC power is approximately 85 kHz. In some embodiments, the AC driver circuit 175 in combination with the first coil L₁ corresponds to the transmitter 160 (FIG. 1B, already discussed). In some embodiments, the first coil L₁ (and, alternatively, with additional circuitry) corresponds to the transmitter 160 while the AC driver circuit 175 is remote relative to the transmitter 160. In embodiments, the second coil L₂ corresponds to the receiver 130 (FIGS. 1A-1B, already discussed). In some embodiments, the second coil L₂ in combination with the rectifier 180 corresponds to the receiver 130. The rectifier 180 can correspond to the rectifier 140 (FIG. 1A, already discussed), and the storage device 190 can correspond to the battery 120 (FIG. 1A, already discussed).

When the first coil L₁ and the second coil L₂ are in proximity and when power is applied by the AC driver circuit 175, the magnetic field 177 passes (e.g., permeates or radiates) into the second coil L₂. The second coil L₂ then transfers power from the magnetic field 177 into electric power, via inductive coupling, to be supplied via the rectifier 180 to the storage device 190. In this way, the second coil L₂ generates (e.g., provides) electric power when exposed to a changing magnetic field. The magnetic field 177 can correspond to the magnetic field 164 (FIG. 1B, already discussed). The second coil L₂ can include a plurality of coils electrically coupled, for example, in parallel. In embodiments, the coil L2 and the rectifier 180 are electrically coupled to form a wireless charging apparatus 185. In embodiments, the wireless charging circuit 170 can include additional components not shown in FIG. 1C.

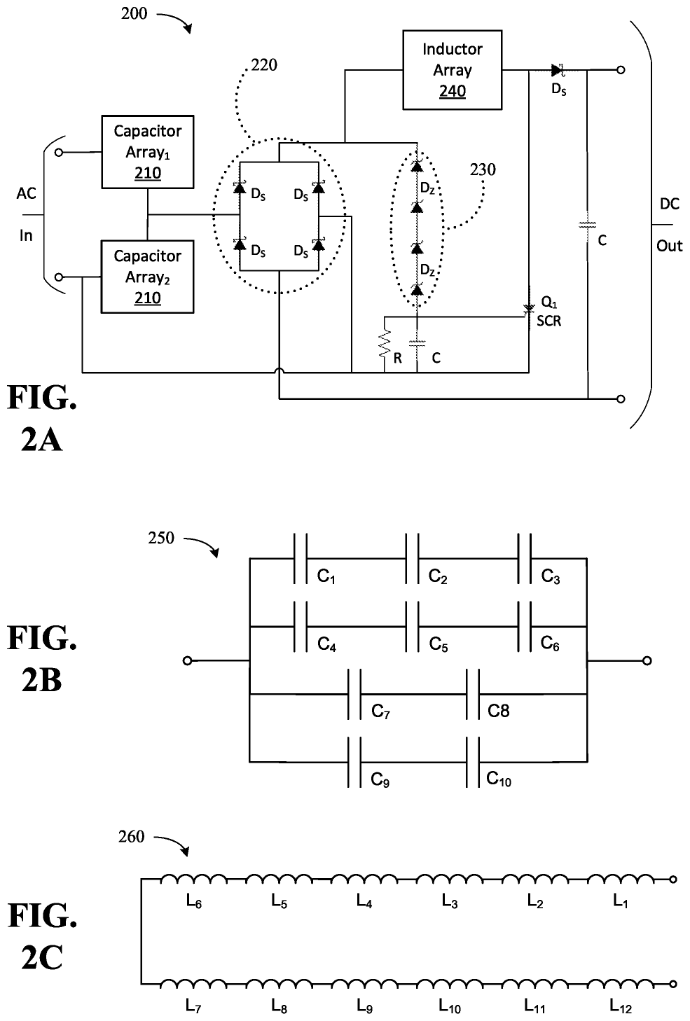

FIG. 2A provides a circuit diagram illustrating an example of a rectifier circuit 200 for use in an electric vehicle wireless inductive charging system such as, e.g., the rectifier 140 of the wireless inductive charging system 100 (FIG. 1A) according to one or more embodiments, with reference to components and features described herein including but not limited to the figures and associated description. As shown in the example rectifier circuit 200 of FIG. 2A, the rectifier circuit 200 includes, among other components, a pair of capacitor arrays 210, a switch array 220 (shown as an array of Schottky diodes), an array 230 of Zener diodes, and an inductor array 240, along with other circuit components. The rectifier circuit 200 has an alternating current (AC) input and a direct current (DC) output as shown. The AC input provides an AC input power source (e.g., from the receiver 130 in FIGS. 1A-1B, already discussed). In some embodiments, each of the capacitor arrays 210 has the same circuit arrangement of capacitors (such as, e.g., the circuit arrangement shown in FIG. 2B herein); in some embodiments, the capacitor arrays 210 can each be a different circuit arrangement of capacitors. The Zener diodes help prevent damage from voltage overshooting. The more Zener diodes that are connected in series in the array, the higher the allowable voltage the circuit will have.

It will be understood that the rectifier circuit 200 shown in FIG. 2A is an example of a circuit that can be used as a rectifier in a wireless inductive charging system for an electric vehicle, and that other circuits can also be used having similar circuit components with different arrangements, different (or additional or fewer) circuit components, and/or a combination of different circuit components and different arrangements of the circuit components. For example, in some embodiments the rectifier circuit 200 has fewer than two capacitor arrays 210; in some embodiments the rectifier circuit 200 has more than two capacitor arrays 210. As another example, in some embodiments the rectifier circuit 200 has more than one inductor array 240. As another example, in some embodiments the rectifier circuit 200 has a switch array 220 containing switches other than Schottky diodes.

The rectifier circuit 200 to be used in the rectifier 140 can be designed to provide a variety of power levels. For example, in some embodiments the rectifier circuit 200 is designed to provide approximately 3 kW output power (such as, e.g., approximately 3.6 kW). As another example, in some embodiments the rectifier circuit 200 is designed to provide approximately 7 kW output power (such as, e.g., approximately 7.2 kW). As another example, in some embodiments the rectifier circuit 200 is designed to provide approximately 11 kW output power.

FIG. 2B provides a circuit diagram illustrating an example of a capacitor array 250 for use in a rectifier circuit such as the rectifier circuit 200 (FIG. 2A) according to one or more embodiments, with reference to components and features described herein including but not limited to the figures and associated description. In some embodiments, the capacitor array 250 corresponds to each of the capacitor arrays 210 (FIG. 2A, already discussed). In the example shown in FIG. 2B, the capacitor array 250 has ten (10) capacitors arranged in a parallel-series configuration. In some embodiments, the capacitor array 250 has fewer than ten capacitors; in some embodiments, the capacitor array 250 has more than ten capacitors. In some embodiments, the capacitor array 250 has fifty (50) capacitors or more. In some embodiments, the capacitor array 250 has capacitors arranged in a different configuration than illustrated in the example of FIG. 2B.

As mentioned above, the rectifier 140 (FIG. 1A, already discussed) is designed to reduce the amount of vertical space needed to place the rectifier 140 assembly on the bottom of the EV 110. According to embodiments, the capacitor array 250 used in the rectifier circuit 200 for the rectifier 140 includes thin surface-mount capacitors to reduce the height of the circuit components in the rectifier 140. In some embodiments, the thin surface-mount capacitors are thin ceramic capacitors. In some embodiments, a greater number of thin surface-mount capacitors are used (as compared to a smaller number of bulky capacitors) to reduce the height of the circuit components in the rectifier 140. The number of capacitors used in the capacitor array 250, the size (e.g., capacitance) of the capacitors, and/or the arrangement of the capacitors in the array can depend on one or more design criteria, such as, e.g., power requirements, AC frequency, etc. The number of capacitors can be determined, for example, by both the total power level and the specifications of each capacitor. For example, with a target capacitance, a variety of capacitance values (and, hence, the size of an individual capacitor) for each capacitor in the array can vary depending on the number and arrangement of capacitors. The example capacitor array illustrated in FIG. 2B can be used in embodiments to achieve a balance of cost and thickness reduction.

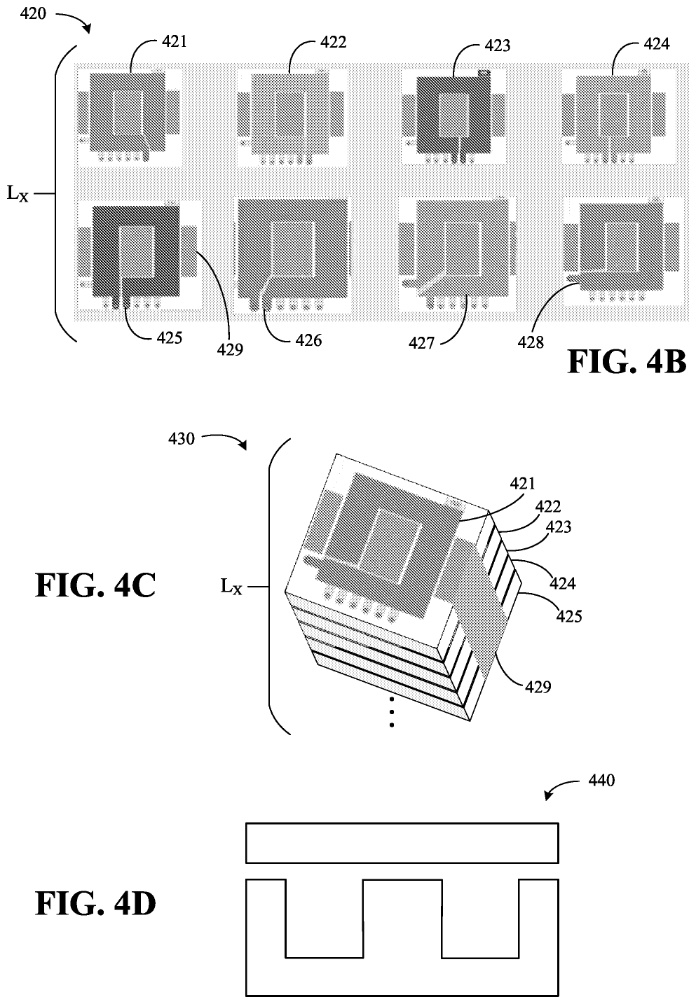

FIG. 2C provides a circuit diagram illustrating an example of an inductor array 260 for use in a rectifier circuit such as the rectifier circuit 200 (FIG. 2A) according to one or more embodiments, with reference to components and features described herein including but not limited to the figures and associated description. In some embodiments, the inductor array 260 corresponds to the inductor array 240 (FIG. 2A, already discussed). In the example shown in FIG. 2C, the inductor array 260 has twelve (12) inductors arranged in a series configuration. In some embodiments, the inductor array 260 has fewer than twelve inductors; in some embodiments, the inductor array 260 has more than twelve inductors. In some embodiments, the inductor array 260 includes a range of approximately five (5) to twenty (20) inductors. In some embodiments, the inductor array 260 has inductors arranged in a different configuration than illustrated in the example of FIG. 2C. The number of inductors used in the inductor array 260, the size (e.g., inductance) of the inductors, and/or the arrangement of the inductors in the array can depend on one or more design criteria, such as, e.g., power requirements, AC frequency, etc. The number of inductors can be determined, for example, by both the total power level and the specifications of each inductor. For example, a larger number of smaller inductors can be used to achieve overall size or thickness reduction. As an additional consideration for inductors, as described herein with reference to FIGS. 4A-4D the inductor design uses PCB windings, which can limit the number of metallic windings (e.g., copper coils) based on the number of layers of the inductor PCB. The more layers in the inductor PCB, the larger an individual inductor can be (more PCB windings), but the board will be thicker (and more costly).

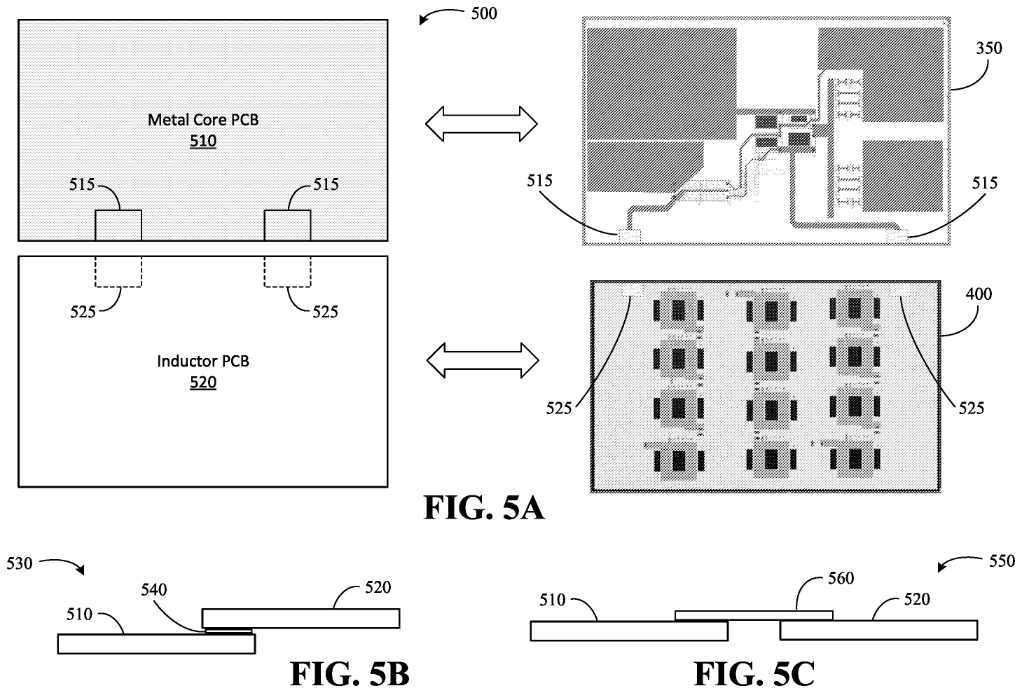

As mentioned above, the rectifier 140 (FIG. 1A, already discussed) is designed to reduce the amount of vertical space needed to place the rectifier 140 assembly on the bottom of the EV 110. According to embodiments, the inductor array 260 used in the rectifier circuit 200 for the rectifier 140 includes inductors (e.g., PCB windings or PCB winding inductors) to reduce the height of the circuit components in the rectifier 140. As described more fully herein with reference to FIGS. 4A-4B and 5A-5C herein, the inductors are provided on a separate board from some or all of the other components of the rectifier circuit 200.

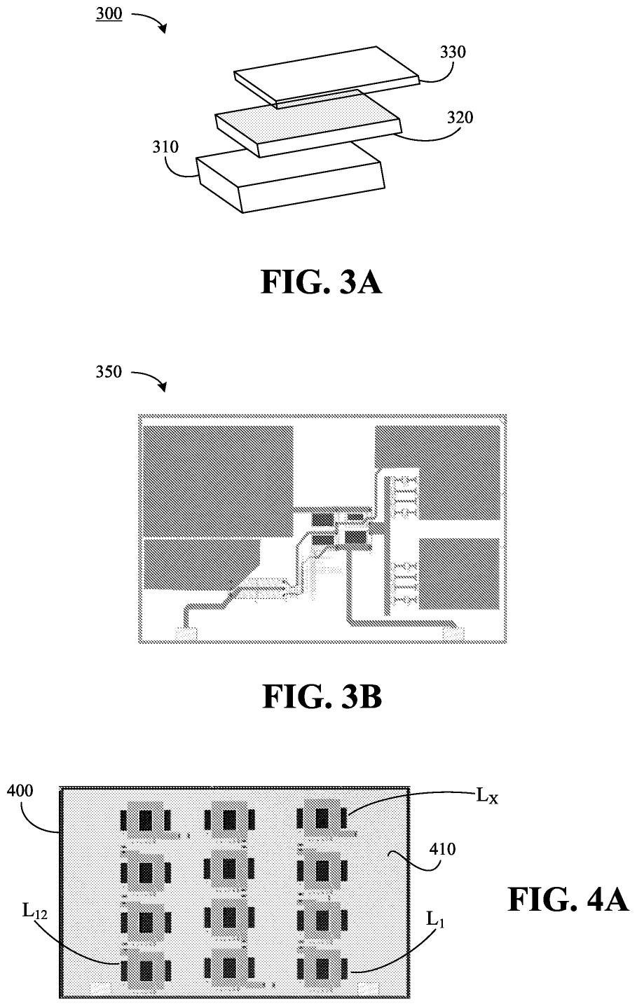

FIG. 3A provides a diagram illustrating an example of a metal core PCB 300 for use in a rectifier apparatus such as, e.g., the rectifier 140 (FIG. 1A) according to one or more embodiments, with reference to components and features described herein including but not limited to the figures and associated description. The metal core PCB 300 includes several layers, including a metal layer 310, a dielectric layer 320 and a circuit layer 330.

The metal layer 310 forms a metal substrate that is thermally conductive. The metal layer 310 provides for the transfer of heat from the other layers (such as the circuit layer 330), and dissipates the heat via exposure to air or other portions of the rectifier apparatus. For example, in embodiments the metal layer 310 is on a bottom side of the rectifier apparatus, and the metal layer 310 dissipates the heat via exposure to air circulating around the rectifier apparatus. In particular, heat from the switches (e.g., the switch array 220) and/or other power components of the rectifier circuit 200, as placed on the circuit layer 330, are dissipated via the metal layer 310. In this way, the rectifier apparatus can dissipate heat without the need for an additional cooling mechanism such as heat pipes. In embodiments, the metal layer 310 is (or includes) aluminum. In some embodiments the metal layer 310 can be copper or a copper alloy. Other metal alloys can be used if they have sufficient thermal conductivity and can be bonded with the dielectric layer 320.

As illustrated in FIG. 3A, the dielectric layer 320 is provided on a surface of the metal layer 310 (e.g., the dielectric layer 320 is adjacent to the metal layer 310). The dielectric layer 320 provides a thin, electrically-insulating layer to provide for placement of the circuit layer 330. In embodiments, the dielectric layer 320 is (or includes) a ceramic material. In some embodiments, the dielectric layer 320 can include a dielectric polymer material. Other dielectric materials can be used if they provide good electrical isolation and can be bonded with the metal layer 310. In some embodiments, a dielectric material with high ductility may be preferable if there is risk that the metal layer 310 expands significantly due to the heat dissipation through the metal layer.

As further illustrated in FIG. 3A, the circuit layer 330 is provided on an opposite surface of the dielectric layer 320 relative to the metal layer 310 (e.g., the circuit layer 330 is adjacent to the dielectric layer 320, but not adjacent to the metal layer 310). The circuit layer 330 includes copper traces and circuit components such as, e.g., circuit components from the rectifier circuit 200. For example, circuit components forming the power loop of the rectifier circuit 200 including, e.g., the capacitor arrays 210 and the switch array 220, are included on the circuit layer 330. The inductor array 240, however, is not included on the circuit layer 330 of the metal core PCB 300; instead, as described with reference to FIG. 4A herein, the inductor array 240 is included on a separate inductor PCB.

FIG. 3B provides a top view diagram illustrating an example of a metal core PCB 350 for use in a rectifier apparatus such as, e.g., the rectifier 140 (FIG. 1A) and/or the rectifier 180 (FIG. 1C) according to one or more embodiments, with reference to components and features described herein including but not limited to the figures and associated description. In embodiments, the metal core PCB 350 corresponds to the metal core PCB 300 (FIG. 3A, already discussed). As shown in FIG. 3B, the example metal core PCB 350 has a circuit layer (such as, e.g., the circuit layer 330 of FIG. 3A, already discussed) that can include a layout having a variety of metal traces (e.g., copper traces), placement of circuit components and connection pads. The layout shown in FIG. 3B is for illustrative purposes only, and other layouts can be used according to circuit board design criteria for a particular implementation.

FIG. 4A provides a diagram illustrating an example of an inductor PCB 400 for use in a rectifier apparatus according to one or more embodiments, with reference to components and features described herein including but not limited to the figures and associated description. The inductor PCB 400 includes a non-metallic printed circuit board as a substrate 410 with a number of inductors formed (i.e., embedded) therein. In embodiments the non-metallic substrate 410 of the inductor PCB 400 is (or includes) any material suitable for a printed circuit board, such as, e.g., a fiberglass composite material (e.g., fiberglass/epoxy material FR4).

The inductors in the inductor PCB 400 correspond to the inductor array 240 (FIG. 2A, already discussed) and/or to the inductor array 260 (FIG. 2C, already discussed). As illustrated in FIG. 4A, the example inductor PCB 400 includes twelve (12) inductors (some of which are labeled as L₁, L_{X}, L₁₂). It will be understood, however, that an inductor PCB 400 can include fewer than twelve inductors or more than twelve inductors, and that the arrangement of the inductors on the inductor PCB 400 can vary, depending on design requirements including the circuit design of the inductor array 260. The inductor PCB 400 can include a layout having a variety of metal traces (e.g., copper traces) and connection pads for connecting the various inductors. In some embodiments, the inductor PCB 400 can include other components such as, e.g., one or more other components of the rectifier circuit 200 not in the power loop or otherwise not generating significant heat. For example, other driving circuits (not shown in FIG. 2A, e.g. for more complex operation of the rectifier) can be included in the inductor PCB 400.

FIGS. 4B-4D provide diagrams illustrating an example of an inductor L_{X} for an inductor PCB such as, e.g., the inductor PCB 400, for use in a rectifier apparatus according to one or more embodiments, with reference to components and features described herein including but not limited to the figures and associated description. The inductor L_{X} is representative of and corresponds to any one of the inductors on the inductor PCB 400 (such as, e.g., the inductor L₁, the inductor L₁₂, etc.). Each inductor L_{X} is a multi-level inductor having a plurality of PCB windings, each winding on a separate level. The PCB windings are metallic windings (e.g., copper coils or windings).

Turning to FIG. 4B, a diagram 420 illustrates the example PCB L_{X} in an “exploded” view showing various levels of the inductor L_{X}, each level having a PCB winding, including a first winding 421 on a first level, a second winding 422 on a second level, a third winding 423 on a third level, a fourth winding 424 on a fourth level, a fifth winding 425 on a fifth level, a sixth winding 426 on a sixth level, a seventh winding 427 on a seventh level, and an eighth winding 428 on an eighth level. The inductor L_{X} also includes a magnetic core 429 (e.g., a ferrite core) embedded in the PCB with the PCB windings. The PCB windings in the various levels are electrically coupled by via holes and/or copper traces. As one example, the PCB windings can be electrically coupled or connected in parallel. As another example, the PCB windings can be electrically coupled or connected in series. The arrangement of the PCB windings, and the specific design of the each PCB windings including, e.g., the width of the trace, the number of turns, and/or the overall size of the winding, can be selected as appropriate for the requirements of the inductor array 240 and/or the inductor array 260.

While FIG. 4B illustrates an example inductor L_{X} having eight (8) windings/levels, it will be understood that the inductor L_{X} can include fewer than eight windings/levels or more than eight windings/levels. In some embodiments, the number of PCB windings/levels of the Inductor L_{X} includes a range of approximately four (4) to sixteen (16) windings/levels. The number of PCB windings and levels for an inductor L_{X} will depend on design criteria.

Turning now to FIG. 4C, a diagram 430 illustrates an example PCB L_{X} in a “stacked” view showing the Inductor L_{X} as a stacked arrangement of PCB windings 421, 422, 423, 424, 425 etc. The example PCB L_{X} in FIG. 4C corresponds to the example PCB L_{X} in FIG. 4B. As illustrated in FIG. 4C, the Inductor L_{X} includes the embedded magnetic core 429 which is common to all of the PCB windings 421, 422, etc.

An example of a ferrite core 440 for use in a PCB inductor (such as the example PCB L_{X}) is illustrated in FIG. 4D. The ferrite core 440 is shown as a side view. The PCB windings for the PCB inductor will surround the two spaces in the ferrite core 440. In embodiments the ferrite core 440 corresponds to the magnetic core 429 (FIGS. 4B-4C, already discussed).

FIGS. 5A-5C provide diagrams illustrating examples of a rectifier apparatus 500 (e.g., a dual rectifier board apparatus) for use in a wireless inductive charging system according to one or more embodiments, with reference to components and features described herein including but not limited to the figures and associated description. In embodiments the rectifier apparatus 500 corresponds to the rectifier 140 (FIG. 1A, already discussed) and/or the rectifier 180 (FIG. 1C, already discussed).

Turning to FIG. 5A, the rectifier apparatus 500 is a dual-PCB arrangement including a first PCB, which is a metal core PCB 510, and a second PCB, which is an inductor PCB 520. In embodiments, the metal core PCB 510 corresponds to the metal core PCB 300 (FIG. 3A, already discussed) and/or to the metal core PCB 350 (FIG. 3B, already discussed). In embodiments, the inductor PCB 520 corresponds to the inductor PCB 400 (FIG. 4A, already discussed). The metal core PCB 510 includes at least two contact pads 515 to provide for electrical coupling between the metal core PCB 510 and the inductor PCB 520. In embodiments, the contact pads 515 are located on or near an edge of the metal core PCB 510. Similarly, the inductor PCB 520 includes at least two contact pads 525 to provide for electrical coupling between the inductor PCB 520 and the metal core PCB 510.

In embodiments, the metal core PCB 510 and/or the inductor PCB 520 include additional contact pads or contact points (not shown in FIG. 5A) to provide electrical coupling to an AC input power source (such as, e.g., the AC input as shown in in the rectifier circuit 200, FIG. 2A) and/or electrical coupling to a DC output power (such as, e.g., the DC output as shown in in the rectifier circuit 200, FIG. 2A). In addition, in embodiments the rectifier apparatus 500 can include a housing and/or mounting hardware (not shown in FIG. 5A).

In embodiments, the contact pads 525 are located on or near an edge of the inductor PCB 520. Using the contact pads 515 and the contact pads 525, the metal core PCB 510 and the inductor PCB 520. For example, this provides for coupling an inductor array (such as, e.g., the inductor array 240 in FIG. 2A and/or the inductor array 260 in FIG. 2C) to other portions of a rectifier circuit such as, e.g., other portions of the rectifier circuit 200 in FIG. 2A. For example, the other portions of the rectifier circuit 200 can be formed on the circuit layer 330 of the metal core PCB 300 (FIG. 3A, already discussed). In embodiments, the metal core PCB 510 and the inductor PCB 520 are aligned such that, using the contact pads 515 and the contact pads 525 on each respective board, they provide for convenient and/or relatively simple electrical coupling between the metal core PCB 510 and the inductor PCB 520.

Turning now to FIG. 5B, a side view diagram 530 illustrates an example of arranging and electrically coupling the metal core PCB 510 and the inductor PCB 520. In the example illustrated in FIG. 5B, the metal core PCB 510 and the inductor PCB 520 are arranged such that the two boards overlap, with two of the contact pads 515 directly adjacent to two of the contact pads 525. For example, as so aligned the contact pads 515 of the metal core PCB 510 face in an upward direction while the contact pads 525 of the inductor PCB 520 face in a downward direction and directly over top of the respective contact pads 515. Each contact pad 515 is directly connected to a counterpart contact pad 525 via, e.g., solder 540.

Turning now to FIG. 5C, a side view diagram 550 illustrates another example of arranging and electrically coupling the metal core PCB 510 and the inductor PCB 520. In the example illustrated in FIG. 5C, the metal core PCB 510 and the inductor PCB 520 are arranged such that the two boards are horizontally adjacent, with two of the contact pads 515 directly adjacent to two of the contact pads 525. For example, as so aligned the contact pads 515 of the metal core PCB 510 and the contact pads 525 of the inductor PCB 520 face in an upward direction. Each contact pad 515 is directly connected to a counterpart contact pad 525 via, e.g., a high-current connector 560 such as, e.g., a busbar, wire cable, flexible printed circuit (FPC) or other electrical connector. It will be understood that other board arrangements for arranging and electrically coupling the metal core PCB 510 and the inductor PCB 520 can be used. For example, if space permits, one board can be mounted at an angle (e.g., 90 degrees) relative to the other board.

Thus, for example, the rectifier apparatus 500 includes a first printed circuit board (PCB) 510 comprising a plurality of layers, the plurality of layers including a metal layer 310, a dielectric layer 320 provided on a surface of the metal layer, and a circuit layer 330 provided on an opposite surface of the dielectric layer 320 relative to the metal layer 310, the circuit layer including copper traces and circuit components, the circuit components including a capacitor array 250, and a second PCB 520 comprising a non-metallic substrate 410 and a plurality of inductors L_{X} formed in the non-metallic substrate 410, each inductor L_{X} including a magnetic core 429 and a plurality of metallic windings, wherein the plurality of inductors L_{X} are electrically coupled to form an inductor array 260, where the circuit layer 330 of the first PCB 510 and the inductor array 260 of the second PCB 520 are electrically coupled to form a rectifier circuit 200 to provide direct current (DC) power.

In embodiments, the first PCB 510 further includes a first pair of contact pads 515 to provide electrical coupling to the circuit layer 330, the second PCB 520 further includes a second pair of contact pads 525 to provide electrical coupling to the inductor array 260, and the circuit layer 330 of the first PCB 510 and the inductor array 260 of the second PCB 520 are electrically coupled via the first pair of contact pads 515 and the second pair of contact pads 525. In embodiments, the first PCB 510 is arranged adjacent to the second PCB 520 such that the first pair of contact pads 515 are aligned with and in direct electrical contact with the second pair of contact pads 525. In embodiments, the metal layer 310 includes aluminum. In embodiments, the dielectric layer 320 includes a ceramic material. In embodiments, the capacitor array 250 comprises a plurality of thin surface-mount capacitors. In embodiments, for each inductor L_{X}, the plurality of metallic windings are arranged in stacked layers in the non-metallic substrate 410. In embodiments, the non-metallic substrate 410 comprises a fiberglass composite material.

In embodiments, an electric vehicle wireless charging apparatus (such as, e.g., the wireless charging apparatus 185 in FIG. 1C) includes a rectifier (such as, e.g., the rectifier apparatus 500 in FIGS. 5A-5C) and a receiver (such as, e.g., the receiver 130 in FIGS. 1A-1B) electrically coupled to the rectifier, the receiver comprising an inductive coil to generate electric power when exposed to a changing magnetic field. In embodiments, the rectifier and the receiver are arranged in a stacked formation.

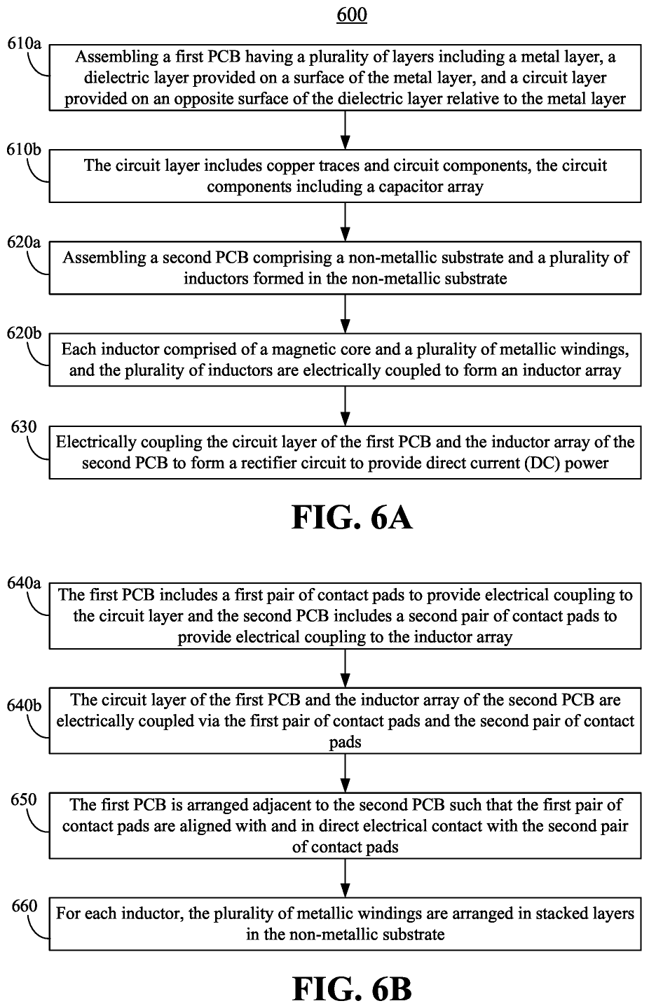

FIGS. 6A-6B provide flowcharts illustrating an example method 600 of constructing a rectifier apparatus for a wireless inductive charging system according to one or more embodiments, with reference to components and features described herein including but not limited to the figures and associated description. The rectifier apparatus can include or correspond to the rectifier apparatus 500, and components thereof, as described herein with reference to FIGS. 1A-1C, 2A-2C, 3A-3B, 4A-4D, and 5A-5C.

Turning to FIG. 6A, construction of a rectifier apparatus for a wireless inductive charging system for use in an electric vehicle is described. Block 610a provides for assembling a first PCB having a plurality of layers including a metal layer, a dielectric layer provided on a surface of the metal layer, and a circuit layer provided on an opposite surface of the dielectric layer relative to the metal layer, where at block 610b the circuit layer includes copper traces and circuit components, the circuit components including a capacitor array. Block 620a provides for assembling a second PCB comprising a non-metallic substrate and a plurality of inductors formed in the non-metallic substrate, where at block 620b each inductor is comprised of a magnetic core and a plurality of metallic windings, and where the plurality of inductors are electrically coupled to form an inductor array. Block 630 provides for electrically coupling the circuit layer of the first PCB and the inductor array of the second PCB to form a rectifier circuit to provide direct current (DC) power.

Turning now to FIG. 6B, at block 640a, the first PCB includes a first pair of contact pads to provide electrical coupling to the circuit layer and the second PCB includes a second pair of contact pads to provide electrical coupling to the inductor array. At block 640b the circuit layer of the first PCB and the inductor array of the second PCB are electrically coupled via the first pair of contact pads and the second pair of contact pads. At block 650 the first PCB is arranged adjacent to the second PCB such that the first pair of contact pads are aligned with and in direct electrical contact with the second pair of contact pads. At block 660, for each inductor, the plurality of metallic windings are arranged in stacked layers in the non-metallic substrate.

The above described methods and systems may be readily combined together if desired. The term “coupled” may be used herein to refer to any type of relationship, direct or indirect, between the components in question, and may apply to electrical, mechanical, fluid, optical, electromagnetic, electromechanical or other connections, including logical connections via intermediate components (e.g., device A may be coupled to device C via device B). In addition, the terms “first,” “second,” etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A, B, C; A and B; A and C; B and C; or A, B and C.

Those skilled in the art will appreciate from the foregoing description that the broad techniques of the embodiments of the present disclosure can be implemented in a variety of forms. Therefore, while the embodiments of this disclosure have been described in connection with particular examples thereof, the true scope of the embodiments of the disclosure should not be so limited since other modifications will become apparent to the skilled practitioner upon a study of the drawings, specification, and following claims.

We claim:

1. A rectifier apparatus for a wireless inductive charging system comprising:
a first printed circuit board (PCB) comprising a plurality of layers, the plurality of layers including:
a metal layer;
a dielectric layer provided on a surface of the metal layer; and
a circuit layer provided on an opposite surface of the dielectric layer relative to the metal layer, the circuit layer including copper traces and circuit components, the circuit components including a capacitor array; and
a second PCB comprising:
a non-metallic substrate; and
a plurality of inductors formed in the non-metallic substrate, each inductor comprised of a magnetic core and a plurality of metallic windings, wherein the plurality of inductors are electrically coupled to form an inductor array;
wherein the circuit layer of the first PCB and the inductor array of the second PCB are electrically coupled to form a rectifier circuit to provide direct current (DC) power.

2. The rectifier apparatus of claim 1, wherein:
the first PCB further comprises a first pair of contact pads to provide electrical coupling to the circuit layer;
the second PCB further comprises a second pair of contact pads to provide electrical coupling to the inductor array; and
the circuit layer of the first PCB and the inductor array of the second PCB are electrically coupled via the first pair of contact pads and the second pair of contact pads.

3. The rectifier apparatus of claim 2, wherein the first PCB is arranged adjacent to the second PCB such that the first pair of contact pads are aligned with and in direct electrical contact with the second pair of contact pads.

4. The rectifier apparatus of claim 1, wherein the metal layer comprises aluminum.

5. The rectifier apparatus of claim 4, wherein the dielectric layer comprises a ceramic material.

6. The rectifier apparatus of claim 1, wherein the capacitor array comprises a plurality of thin surface-mount capacitors.

7. The rectifier apparatus of claim 1, wherein, for each inductor, the plurality of metallic windings are arranged in stacked layers in the non-metallic substrate.

8. The rectifier apparatus of claim 7, wherein the non-metallic substrate comprises a fiberglass composite material.

9. A method of constructing a rectifier apparatus for a wireless inductive charging system comprising:
assembling a first printed circuit board (PCB) comprising a plurality of layers, the plurality of layers including:
a metal layer;
a dielectric layer provided on a surface of the metal layer; and
a circuit layer provided on an opposite surface of the dielectric layer relative to the metal layer, the circuit layer including copper traces and circuit components, the circuit components including a capacitor array;
assembling a second PCB comprising:
a non-metallic substrate; and
a plurality of inductors formed in the non-metallic substrate, each inductor comprised of a magnetic core and a plurality of metallic windings, wherein the plurality of inductors are electrically coupled to form an inductor array; and
electrically coupling the circuit layer of the first PCB and the inductor array of the second PCB to form a rectifier circuit to provide direct current (DC) power.

10. The method of claim 9, wherein the first PCB further comprises a first pair of contact pads to provide electrical coupling to the circuit layer, and
wherein the second PCB further comprises a second pair of contact pads to provide electrical coupling to the inductor array; and
further comprising electrically coupling the circuit layer of the first PCB and the inductor array of the second PCB via the first pair of contact pads and the second pair of contact pads.

11. The method of claim 10, wherein the first PCB is arranged adjacent to the second PCB such that the first pair of contact pads are aligned with and in direct electrical contact with the second pair of contact pads.

12. The method of claim 9, wherein the metal layer comprises aluminum.

13. The method of claim 12, wherein the dielectric layer comprises a ceramic material.

14. The method of claim 9, wherein the capacitor array comprises a plurality of thin surface-mount capacitors.

15. The method of claim 9, wherein, for each inductor, the plurality of metallic windings are arranged in stacked layers in the non-metallic substrate.

16. The method of claim 15, wherein the non-metallic substrate comprises a fiberglass composite material.

17. An electric vehicle wireless charging apparatus comprising:
a rectifier comprising:
a first printed circuit board (PCB) comprising a plurality of layers, the plurality of layers including:
a metal layer;
a dielectric layer provided on a surface of the metal layer; and
a circuit layer provided on an opposite surface of the dielectric layer relative to the metal layer, the circuit layer including copper traces and circuit components, the circuit components including a capacitor array; and
a second PCB comprising:
a non-metallic substrate; and
a plurality of inductors formed in the non-metallic substrate, each inductor comprised of a magnetic core and a plurality of metallic windings, wherein the plurality of inductors are electrically coupled to form an inductor array;
wherein the circuit layer of the first PCB and the inductor array of the second PCB are electrically coupled to form a rectifier circuit to provide direct current (DC) power; and
a receiver electrically coupled to the rectifier, the receiver comprising an inductive coil to generate electric power when exposed to a changing magnetic field.

18. The electric vehicle wireless charging apparatus of claim 17, wherein the rectifier and the receiver are arranged in a stacked formation.

19. The electric vehicle wireless charging apparatus of claim 18, wherein:
the first PCB further comprises a first pair of contact pads to provide electrical coupling to the circuit layer;
the second PCB further comprises a second pair of contact pads to provide electrical coupling to the inductor array;
the circuit layer of the first PCB and the inductor array of the second PCB are electrically coupled via the first pair of contact pads and the second pair of contact pads; and
wherein the first PCB is arranged adjacent to the second PCB such that the first pair of contact pads are aligned with and in direct electrical contact with the second pair of contact pads.

20. The electric vehicle wireless charging apparatus of claim 19, wherein:
the metal layer comprises aluminum;
the dielectric layer comprises a ceramic material;
the capacitor array comprises a plurality of thin surface-mount capacitors;
the non-metallic substrate comprises a fiberglass composite material; and
for each inductor, the plurality of metallic windings are arranged in stacked layers in the non-metallic substrate.
